(19) United States
(12) Patent Application Publication
(10) Pub. No.: US 2019/0169444 A1
(43) Pub. Date: Jun. 6, 2019

(54) ANTI-WETTING COATING

(71) Applicant: Applied Materials, Inc., Santa Clara, CA (US)

(72) Inventor: Kaushal Gangakhedkar, San Jose, CA (US)

(21) Appl. No.: 16/203,456

(22) Filed: Nov. 28, 2018

Related U.S. Application Data
(60) Provisional application No. 62/594,181, filed on Dec. 4, 2017.

(51) Int. Cl. C09D 5/08; C23C 14/08; C23C 16/40; C04B 41/45; C04B 41/48; C04B 41/50

(52) U.S. Cl. CPC C09D 5/08; C23C 14/083; C23C 16/405; C23C 16/45525; C04B 41/4846; C04B 41/5096; C04B 41/4531

(57) ABSTRACT

An anti-wetting coating including a ceramic material and a second material that may include, but not be limited to, pure amorphous silicon, hydrogenated silicon, silicon hydride, polytetrafluoroethylene (PTFE), perfluoroalkoxy alkanes (PFA), fluorinated ethylene propylene (FEP), polyvinylidene fluoride (PVDF), low density polyethylene (PELD), polyamide, polyimide, polyimide-amide, polyurea, polyurethane, polythiurea, polyester, polyimine, and combinations thereof.

### RELATED APPLICATIONS

This application claims priority to U.S. Provisional Patent Application No. 62/594,181, filed Dec. 4, 2017, which is herein incorporated by reference in its entirety.

### TECHNICAL FIELD

Embodiments disclosed herein relate, in general, to anti-wetting coatings for articles, and in particular to anti-wetting coatings that enhance the coated article's corrosion resistance.

### BACKGROUND

In the semiconductor industry, highly corrosive chemicals are used in a variety of processes. These chemicals tend to adsorb onto surfaces that are exposed to them (also known as “wetting”). Additionally, surfaces with complex geometries and/or surfaces of articles that have a high aspect ratio may have residuals of these highly corrosive chemicals. Wetting as well as the accumulation of corrosive residues may increase harm to the article by generating particles which could then contribute to defects in the article.

As device geometries shrink, susceptibility to defects and particle contamination increases, and particle contaminant specifications become more stringent. To minimize defects and particle contamination and increase the lifetime of the article, chamber components, chamber component coatings, substrates and substrate coatings that are resistant to chamber processing conditions, are less likely to corrode, and to generate particle contamination are sought.

### SUMMARY

In an example embodiment, disclosed herein is a component comprising an article and an anti-wetting coating. The anti-wetting coating may comprise a ceramic material and a second material selected from the group consisting of pure amorphous silicon, hydrogenated silicon, silicon hydride, polytetrafluoroethylene (PTFE), perfluoroalkoxy alkanes (PFA), fluorinated ethylene propylene (FEP), polyvinylidene fluoride (PVDF), low density polyethylene (PELD), ethylene tetrafluoroethylene (ETFE), polyamide, polyimide, polyimide-amide, polyurea, polyurethane, polythiurea, polyester, polyimine, and combinations thereof. In some embodiments, the coated component may have a wetting angle of at least about 90°.

In an example embodiment, disclosed herein is a method for forming an anti-wetting coating on an article. The method may comprise coating an article with a ceramic material. The method may further comprise coating the article with a second material selected from the group consisting of pure amorphous silicon, hydrogenated silicon, silicon hydride, PTFE, PFA, FEP, PVDF, PELD, ETFE, polyamide, polyimide, polyimide-amide, polyurea, polyurethane, polythiurea, polyester, polyimine, and combinations thereof to form a coated article. In some embodiments, the anti-wetting coating may have a wetting angle of at least about 90°.

In an example embodiment, disclosed herein is an anti-wetting coating comprising a ceramic material and a second material selected from the group consisting of pure amorphous silicon, hydrogenated silicon, silicon hydride, PTFE, PFA, FEP, PVDF, PELD, ETFE, polyamide, polyimide, polyimide-amide, polyurea, polyurethane, polythiurea, polyester, polyimine, and combinations thereof. In some embodiments, the anti-wetting coating may have a wetting angle of at least about 90°.

### BRIEF DESCRIPTION OF THE DRAWINGS

Embodiments of the present disclosure are illustrated by way of example, and not by way of limitation, in the figures of the accompanying drawings in which like references indicate similar elements. It should be noted that different references to “an” or “one” embodiment in this disclosure are not necessarily to the same embodiment, and such references mean at least one.

FIG. 1 is a sectional view of a coated article, in accordance with an embodiment.

FIG. 2 depicts various surface wetting measurements.

FIG. 3 discloses a method for forming an anti-wetting coating on an article, in accordance with embodiments.

FIG. 4 depicts a mechanism applicable to a variety of atomic layer deposition (ALD) techniques that may be utilized for coating an article, in accordance with an embodiment.

FIG. 5 depicts an exemplary chemical vapor deposition (CVD) system that may be utilized for coating an article, in accordance with an embodiment.

FIG. 6 depicts an exemplary physical vapor deposition (PVD) system that may be utilized for coating an article, in accordance with an embodiment.

### DETAILED DESCRIPTION OF EMBODIMENTS

Amines and silanes are commonly used chemicals as precursors in a variety of industries, such as the semiconductor industry, the light-emitting diode (LED) industry, and the display industry. For instance, amines and silanes may be used to deposit nitride films on substrates and/or on wafers to improve their resistance to fluorine chemistries and/or to form good barriers to moisture and copper. However, precursor molecules, such as SiH₄, chlorosilane, di-chlorosilane, or ammonia (NH₃) have a tendency to adsorb onto the surface of article (such as chamber component where substrates and/or wafers are being processed), leading to prolonged wetting of the precursor molecules on the surface of the article. Such prolonged wetting could be detrimental to the article's quality, performance, and/or lifetime. Additionally, exposure to such precursor molecules could also impact processing time, impact costs associated with processing substrates (e.g., wafers) and lead to metal contamination on an article and/or on the substrates that are processed.

For instance, residual amines and/or silanes on a chamber component may pose issues during atomic layer deposition (ALD) because they may cause an inability to purge a chamber of the amines and/or silanes effectively (e.g., to purge a precursor for the amines and/or silanes). Inefficient precursor purge may cause parasitic chemical vapor deposition (CVD) in addition to the ALD. Parasitic CVD may lead to non-uniform substrate surfaces that may have defects and/or particle generation issues.

Similar issues are observed in chlorine chemistries. Residual chlorine on the article (such as chamber component) attack bare metals of articles (such as chamber components) which corrode the article and lead to the formation of defects and/or particles on processed substrates.

Disclosed herein are anti-wetting coatings for effective purging of these corrosive chemicals. Anti-wetting coatings contemplated herein may comprise an optional ceramic material and a second material selected from the group consisting of pure amorphous silicon, hydrogenated silicon, silicon hydride, polytetrafluoroethylene (PTFE), perfluoroalkoxy alkanes (PFA), fluorinated ethylene propylene (FEP), polyvinylidene fluoride (PVDF), low density polyethylene (PELD), ethylene tetrafluoroethylene (ETFE), polyamide, polyimide, polyimide-amide, polyurea, polyurethane, polythiurea, polyester, polyimine, and combinations thereof. The anti-wetting coating may have a wetting angle of at least 90° or at least 120° so as to repel residual amines and silanes from adsorbing onto the article's surface.

Anti-wetting coatings contemplated herein may be deposited on articles as an anti-wet top coat deposited by atomic layer deposition (ALD), chemical vapor deposition (CVD), molecular layer deposition (MLD) or physical vapor deposition (PVD). Alternatively, the anti-wet coating may be formed, at least partially, by immersion methods in order to fill in pores in a porous ceramic coating and/or smooth rough article surfaces.

When the terms “about” and “approximate” are used herein, this is intended to mean that the nominal value presented is precise within ±10%.

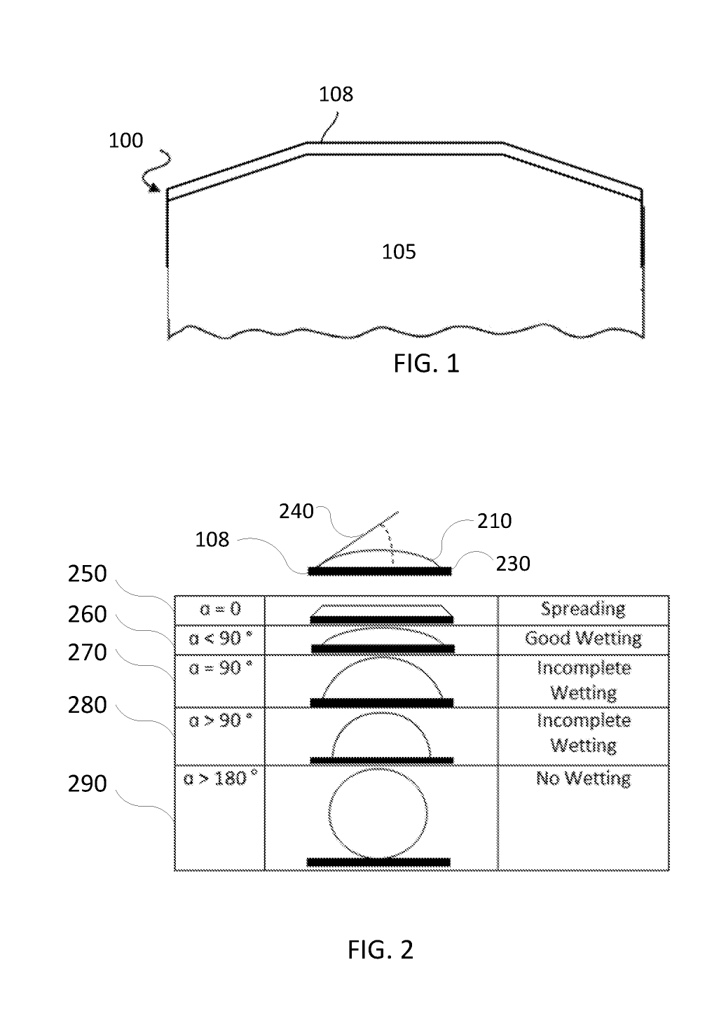

FIG. 1 is a sectional view of a component 100, in accordance with an embodiment. In an embodiment, the component may comprise an article 105 and an anti-wetting coating 108.

Exemplary non limiting articles may be selected from the group consisting of an electrostatic chuck, a nozzle, a gas distribution plate, a shower head, an electrostatic chuck component, a chamber wall, a liner, a liner kit, a gas line, a chamber lid, a nozzle, a single ring, a processing kit ring, a base, a shield, a plasma screen, a flow equalizer, a cooling base, a chamber viewport, a bellow, and so on.

Article 105 may be a ceramic article including an oxide based ceramic article, a nitride based ceramic article and/or a carbide based ceramic article. Examples of oxide based ceramics include SiO₂ (quartz), Al₂O₃, Y₂O₃, and so on. Examples of carbide based ceramics include SiC, Si—SiC, and so on. Examples of nitride based ceramics include AN, SiN, and so on. In some embodiments, article 105 may be aluminum, anodized aluminum, an aluminum alloy (e.g., Al 6061), or an anodized aluminum alloy.

The anti-wetting coating 108 may comprise an optional ceramic material. In some embodiments, the anti-wetting coating 108 may additionally or alternatively comprise a second material that may provide the coating anti-wetting properties. In certain embodiments, the anti-wetting coating 108 may comprise the second material by itself, without a ceramic material (i.e., the second material may be coated directly on article 105). In other embodiments, the ceramic material and the second material together form the anti-wetting coating. In embodiments where the ceramic material and the second material form the anti-wetting coating together, the second material may be deposited as a top anti-wetting coat capping the ceramic material, or the second material may be embedded in the pores defined by a porous ceramic material.

The combination of the ceramic material and the second material may form an anti-wetting coating 108 with one or more properties selected from the group consisting of reduced wettability, lower coefficient of friction, lower water adsorption, higher corrosion resistance, higher erosion resistance, higher melting temperature, and combinations thereof. A higher melting temperature would enable an increase in operating temperature with a reduced risk of crack formation in the article 105.

The ceramic material may comprise a rare earth oxide, a rare earth fluoride, a rare earth oxy-fluoride or other ceramic material. The ceramic material may include Y₂O₃ and Y₂O₃ based ceramics, Y₃Al₅O₁₂ (YAG), Al₂O₃ (alumina), Y₄Al₂O₉ (YAM), YF₃, SiC (silicon carbide), ErAlO₃, GdAlO₃, NdAlO₃, YAlO₃, Si₃N₄ (silicon nitride), AlN (aluminum nitride), TiO₂ (titania), ZrO₂ (zirconia), TiC (titanium carbide), ZrC (zirconium carbide), TiN (titanium nitride), Y₂O₃ stabilized ZrO₂ (YSZ), Er₂O₃ and Er₂O₃ based ceramics, Gd₂O₃ and Gd₂O₃ based ceramics, Er₃Al₅O₁₂ (EAG), Gd₃Al₅O₁₂ (GAG), Nd₂O₃ and Nd₂O₃ based ceramics, a ceramic compound comprising Y₂O₃ and YF₃ (e.g., Y—O—F), a ceramic compound comprising Y₄Al₂O₉ and a solid-solution of Y₂O₃—ZrO₂, a ceramic compound comprising Y₂O₃, Er₂O₃, ZrO₂, Gd₂O₃ and SiO₂, or a combination of any of the above.

The ceramic material may also be based on a solid solution formed by any of the aforementioned ceramics. The ceramic material may also be a multiphase material that includes a solid solution of one or more of the aforementioned materials and one or more additional phase.

With reference to the solid-solution of Y₂O₃—ZrO₂, the ceramic material may include Y₂O₃ at a concentration of 10-90 molar ratio (mol %) and ZrO₂ at a concentration of 10-90 mol %. In some examples, the solid-solution of Y₂O₃—ZrO₂ may include 10-20 mol % Y₂O₃ and 80-90 mol % ZrO₂, may include 20-30 mol % Y₂O₃ and 70-80 mol % ZrO₂, may include 30-40 mol % Y₂O₃ and 60-70 mol % ZrO₂, may include 40-50 mol % Y₂O₃ and 50-60 mol % ZrO₂, may include 60-70 mol % Y₂O₃ and 30-40 mol % ZrO₂, may include 70-80 mol % Y₂O₃ and 20-30 mol % ZrO₂, may include 80-90 mol % Y₂O₃ and 10-20 mol % ZrO₂, and so on.

With reference to the ceramic compound comprising Y₄Al₂O₉ and a solid-solution of Y₂O₃—ZrO₂, in one embodiment the ceramic compound includes 62.93 molar ratio (mol %) Y₂O₃, 23.23 mol % ZrO₂ and 13.94 mol % Al₂O₃. In another embodiment, the ceramic compound can include Y₂O₃ in a range of 50-75 mol %, ZrO₂ in a range of 10-30 mol % and Al₂O₃ in a range of 10-30 mol %. In another embodiment, the ceramic compound can include Y₂O₃ in a range of 40-100 mol %, ZrO₂ in a range of 0.1-60 mol % and Al₂O₃ in a range of 0.1-10 mol %. In another embodiment, the ceramic compound can include Y₂O₃ in a range of 40-60 mol %, ZrO₂ in a range of 35-50 mol % and Al₂O₃ in a range of 10-20 mol %. In another embodiment, the ceramic compound can include Y₂O₃ in a range of 40-50 mol %, ZrO₂ in a range of 20-40 mol % and Al₂O₃ in a range of 20-40 mol %. In another embodiment, the ceramic compound can include Y₂O₃ in a range of 80-90 mol %, ZrO₂ in a range of 0.1-20 mol % and Al₂O₃ in a range of 10-20 mol %. In another embodiment, the ceramic compound can include Y₂O₃ in a range of 60-80 mol %, ZrO₂ in a range of 0.1-10 mol % and Al₂O₃ in a range of 20-40 mol %. In another embodiment, the ceramic compound can include Y₂O₃ in a range of 40-60 mol %, ZrO₂ in a range of 0.1-20 mol % and Al₂O₃ in a range of 30-40 mol %. In other embodiments, other distributions may also be used for the ceramic compound.

In one embodiment, the ceramic material includes or consists of a ceramic compound that includes a combination of Y₂O₃, ZrO₂, Er₂O₃, Gd₂O₃ and SiO₂. In one embodiment, the ceramic compound can include Y₂O₃ in a range of 40-45 mol %, ZrO₂ in a range of 0-10 mol %, Er2O3 in a range of 35-40 mol %, Gd₂O₃ in a range of 5-10 mol % and SiO2 in a range of 5-15 mol %. In a first example, the alternative ceramic compound includes 40 mol % Y₂O₃, 5 mol % ZrO₂, 35 mol % Er₂O₃, 5 mol % Gd₂O₃ and 15 mol % SiO₂. In a second example, the alternative ceramic compound includes 45 mol % Y₂O₃, 5 mol % ZrO₂, 35 mol % Er₂O₃, 10 mol % Gd₂O₃ and 5 mol % SiO₂. In a third example, the alternative ceramic compound includes 40 mol % Y₂O₃, 5 mol % ZrO₂, 40 mol % Er₂O₃, 7 mol % Gd₂O₃ and 8 mol % SiO₂.

With regards to a ceramic material comprising a combination of Y₂O₃ and YF₃, the coating may be a Y—O—F coating that has a single Y—O—F phase or multiple different Y—O—F phases. Some possible Y—O—F phases that the Y—O—F coating may have are YOF ht, YOF rt, YOF tet, Y₂OF₄ (e.g., Y₂OF₄ ht-hp), Y₃O₂F₅ (e.g., Y₃O₂F₅ ht-hp), YO_{0.4}F₂₂ (e.g., YO_{0.4}F₂₂ht-hp), Y₅O₄F₇, Y₆O₅F₈, Y₇O₆F₉, and Y₁₇O₁₄F₂₃. In some embodiments, the ceramic material is a Y—Zr—O—F coating.

Any of the aforementioned ceramic materials may include trace amounts of other materials such as ZrO₂, Al₂O₃, SiO₂, B₂O₃, Er₂O₃, Nd₂O₃, Nb₂O₅, CeO₂, Sm₂O₃, Yb₂O₃, or other oxides. The ceramic materials allows for longer working lifetimes due to the plasma resistance of the ceramic materials and decreased on-wafer or substrate contamination. Beneficially, in some embodiments the ceramic material may be stripped and re-coated without affecting the dimensions of the substrates that are coated.

In an exemplary embodiment, the ceramic material may comprise one or more of yttria (Y₂O₃), silica (SiO₂), alumina (Al₂O₃), erbium oxide (Er₂O₃), gadolinium oxide (Gd₂O₃), zirconia (ZrO₂), boron oxide (B₂O₃), Nd₂O₃, Nb₂O₅, CeO₂, Sm₂O₃, Yb₂O₃, other oxides, Y₃Al₅O₁₂, Y₄Al₂O₉, Er₃Al₅O₁₂, Gd₃Al₅O₁₂, a ceramic compound comprising Y₄Al₂O₉ and a solid-solution of Y₂O₃—ZrO2, and combinations thereof.

The ceramic material may be present in the anti-wetting coating at a concentration of up to about 99 wt %, from about 25 wt % to about 99 wt %, from about 50 wt % to about 99 wt %, from about 70 wt % to about 90 wt %, or from about 75 wt % to about 85 wt %, based on the total weight of the anti-wetting coating.

The second material may be selected from the group consisting of pure amorphous silicon, hydrogenated silicon, silicon hydride, polytetrafluoroethylene (PTFE), prefluoroalkoxy alkanes (PFA), fluorine ethylene propylene (FEP), polyvinylidene fluoride (PVDF), low density polyethylene (PELD), ethylene tetrafluoroethylene (ETFE), polyamide, polyimide, polyimide-amide, polyurea, polyurethane, polythiurea, polyester, polyimine, and combinations thereof. The second materials listed herein may prevent prolonged adsorption of amines and silanes and improve the article's resistance to corrosive chemistries such as chlorine chemistries. Other second materials may be utilized (in addition to the ones listed) so long as incorporating them into the coating would provide an anti-wetting coating having one or more of the following properties: provides anti-adsorption with respect to amines and silanes, repels water, repels dust, repels oil, repels dirt, chemically resistant, is easy to clean and/or improves the article's performance in other applications.

Table 1 below summarizes noteworthy properties of the second materials listed herein.

TABLE 1
Properties of Selected Second Materials

| | Polymers | | | | | |
|---|---|---|---|---|---|---|
| Properties | PTFE | PFA | FEP | PELD | PVDF | ETFE |
| Coefficient of | 0.04-0.1 | 0.2 | 0.08-0.3 | <0.2 | 0.14-0.17 | 0.3-0.4 |
| Friction (D1894) | | | | | | |
| Contact Angle of | 109.4 | 107.1 | 108.5 | — | 89 | 99.2 |
| Water | | | | | | |
| Surface Tension of | 19.4 | 18 | 19.1 | — | 31.6 | — |
| Water | | | | | | |
| Water Absorption | <0.01% | <0.03% | <0.01% | <0.01% | <0.04% | <0.03% |
| 24 hrs, 73° F. (D570) | | | | | | |
| Chemical/Solvent | Excellent | Excellent | Excellent | — | — | Excellent |
| Resistance (D543) | | | | | | |
| Properties | PTFE | PFA | FEP | PELD | PVDF | ETFE |
| Salt Spray Resistance¹ | | | | | | |
| (B-117) | | | | | | |
| on aluminum | 744+ | 1000 | 744+ | — | — | 1000 |
| on steel | 192 | — | — | — | — | — |
| Detergent Resistance² | | | | | | |
| on aluminum | 264 | — | 744 | — | — | — |
| on grit- | 624 | — | 600 | — | — | — |
| blasted | | | | | | |
| aluminum | | | | | | |
| on grit- | 24 | — | 480 | — | — | — |
| blasted steel | | | | | | |
| Weather Resistance | 20 | 10 | 20 | — | — | 15 |
| (Florida Exposure, | | | | | | |
| Years unaffected) | | | | | | |
| Specific Gravity, | 2.15 | 2.15 | 2.15 | 0.93 | 1.78 | 1.76 |
| D792 (gm/cc) | | | | | | |
| Tensile Strength, | 21-34 | 25 (3,600) | 23 (3,400) | — | (7,800) | 40-46 |
| D1457, D1708, D638 | (3,000-5,000) | | | | | (5,800-6,700) |
| [MPa (psi)] | | | | | | |
| Elongation | 300-500 | 300 | 325 | — | 35 | 150-300 |
| D1457, D1708, D638 | | | | | | |
| (%) | | | | | | |
| Flexural Modulus | 496 (72,000) | 586 (85,000) | 586 (85,000) | — | (310,000) | 1,172 (170,000) |
| D790 [MPa (psi)] | | | | | | |
| Folding Endurance | >10⁵ | 10-500 × | 5.80 × 10³ | — | — | 10-27 × |
| D2176 [(MIT) cycles] | | 10³ | | | | 10³ |
| Impact Strength, | 189 (3.5) | No Break | No Break | — | — | No Break |
| D256 [J/m (ft · lb/in)] | | | | | | |
| Hardness, D2240 | 50-65 | 60 | 56 HB | — | — | 72 |
| (Shore D pencil) | HB | | | | | |

¹Salt Spray Resistance: 5% NaCl at 35° C./95° F., hours to failure
²Detergent Resistance: hours to failure
— data not available

As summarized in Table 1, the coefficient of friction of PTFE is between about 0.04-0.1, of PFA is about 0.2, of FEP is between about 0.08-0.3, of PELD is less than about 0.2, and of PVDF is between about 0.14-0.17. A lower coefficient of friction may reduce wetting and make the second material more suitable for forming an anti-wetting coating.

As further summarized in Table 1, the contact angle of water of PTFE is about 109.4°, of PFA is about 107.1°, of FEP is about 108.5°, of PVDF is about 89°, and of ETFE is about 99.2°. A higher contact angle indicates that the second material is less prone to wetting which makes the material more suitable for forming an anti-wetting coating.

As shown in Table 1, the surface tension with water of PTFE is about 19.4. The surface tension with water of PFA is about 18. The surface tension with water of FEP is about 19.1. The surface tension with water of PVDF is about 31.6. Table 1 also indicates that the water absorption (measured in accordance with ASTM D570 for 24 hours at 73° F.) of PTFE is less than about 0.01%. The water absorption of PFA is less than about 0.03%. The water absorption of FEP is less than about 0.01%. The water absorption of PELD is less than about 0.01%. The water absorption of PVDF is less than about 0.04%. The water absorption of ETFE is less than about 0.03%. A lower adsorption value makes a material more suitable for forming an anti-wetting coating.

The second material may be present in the anti-wetting coating at a concentration ranging from about 1 wt % to about 100 wt %, from about 1 wt % to about 75 wt %, from about 1 wt % to about 50 wt %, from about 10 wt % to about 30 wt %, or from about 15 wt % to about 25 wt %, based on the total weight of the anti-wetting coating. In some embodiments, the concentration of the ceramic material and the second material adds up to 100 wt %, based on the total weight of the anti-wetting coating.

Anti-wetting coating 108 may have a thickness of about 50 nm to about 1000 nm, about 75 nm to about 750 nm, or about 100 nm to about 500 nm.

In certain embodiments, anti-wetting coating 108 comprises a multilayer architecture. A “multilayer architecture” as used herein refers to two or more layers of the ceramic material and the second material. In one embodiment, the multilayer architecture comprises two layers with the first layer comprising the ceramic material and the second layer comprising the second material (e.g., a top capping anti-wetting layer).

In some embodiments, the anti-wetting coating comprises a top capping anti-wetting layer which may be a sacrificial layer. For instance, a chamber component may be coated with an anti-wetting coating having a top capping anti-wetting layer. After an X number of wafers processed in said chamber (where X could be 10,000 for example), a process drift and metal contamination may start to occur. The wafer processing may stop and the chamber component may be stripped of any residual anti-wetting coating (or perhaps only stripped of any residual top capping anti-wetting layer) and then re-coated with a new anti-wetting coating (or perhaps only with a top capping anti-wetting layer).

The first layer and the second layer may, independently, have a thickness ranging from about 10 nm to about 490 nm, from about 50 nm to about 450 nm, or from about 100 nm to about 400 nm. In certain embodiments, the second material forms an anti-wet top coat that may be conformal, thin, and/or inert acting as a capping layer for preventing or eliminating active adsorption (wetting) sites on the article's surface. In some embodiments, the second layer of the second material may be thinner than the first layer of the ceramic material. For instance, the first layer may have a thickness ranging from about 300 nm to about 490 nm, from about 400 nm to about 490 nm, from about 450 nm to about 490 nm, or from about 350 nm to about 450 nm. The second layer may have a thickness ranging from about 10 nm to about 200 nm, from about 10 nm to about 100 nm, from about 10 nm to about 50 nm, or from about 50 nm to about 150 nm.

In certain embodiments, anti-wetting coating 108 comprises a porous ceramic material (e.g., a ceramic material that defines pores). The porosity of the ceramic material may range from about 1% to about 50%, from about 2% to about 30%, from about 2% to about 15%, from about 2% to about 10%, or from about 2% to about 5%. In embodiments, the second material fills in the pores in the porous ceramic material.

In embodiments, the second material smooths the surface roughness of the ceramic material. For instance, the ceramic material may have a surface roughness ranging from about 125 μ-in to about 300 μ-in. Upon deposition of the second material, the surface roughness of the final anti-wetting coating may range from about 10 μ-in to about 80 μ-in. It should be understood by one of ordinary skill in the art that surface roughness referred to herein is measured as average surface roughness (Ra).

In some embodiments, the anti-wetting coating includes a porous ceramic material with pores that are filled in with the second material. Additionally, the second material may form a sacrificial anti-wetting layer over the ceramic material, or the combination of the ceramic material and the second material may together form a sacrificial anti-wetting coating. For instance, a chamber component may be coated with an anti-wetting coating having a top capping anti-wetting layer. After an X number of wafers processed in said chamber (where X could be 10,000 for example), a drift and metal contamination may start to occur. The wafer processing may stop and the chamber component may be stripped of any residual anti-wetting layer and then re-coated with a new anti-wetting layer.

The ceramic material, when present, may be deposited by one or more of atomic layer deposition (ALD), chemical vapor deposition (CVD), physical vapor deposition (PVD), molecular layer deposition (MLD), thermal spray, immersion, etc. The second material may be deposited by one or more of ALD, CVD, PVD, e-beam IAD, line of sight technique, or immersion technique.

For anti-wetting coatings where the second material fills in the pores of the ceramic material, the second material may be deposited by immersing the article coated with the ceramic material in a solution of the second material and allowing the solution to seep into the pores of the ceramic material. Alternatively, the second layer may be deposited by molecular layer deposition (MLD).

In some embodiments, the anti-wetting coating comprises a stack of alternating layers of the ceramic material and the second material. The layers of the ceramic material may be formed by ALD and the layers of the second material may be formed by MLD.

In certain embodiments, anti-wetting coatings are conformal making them suitable for coating articles having large aspect ratios (e.g. of about 10:1 to about 300:1) and complex three dimensional geometries and/or complex surface features. The anti-wetting coating may also conformally cover such features with a substantially uniform thickness. The anti-wetting coating may have a conformal coverage of the underlying surface that is coated (including coated surface features) with a uniform thickness having a thickness variation of less than about +/−20%, a thickness variation of less than about +/−10%, or a thickness variation of less than about +/−5%.

Anti-wetting coatings according to embodiments may be inert. Anti-wetting coatings according to embodiments have a wetting angle of at least about 90° or at least about 180°. Characterization of the degree of wetting is explained in further detail with respect to FIG. 2 below.

FIG. 2 depicts various surface wetting measurements. Similar measurements may be utilized for measuring wetting propensity of the anti-wetting coating 108 discussed herein. Numeral 210 illustrates a liquid in contact with the anti-wetting coating. Liquids that may be in contact with anti-wetting coating 108 may include one or more of halogen-containing solutions and/or gases, such as C₂F₆, SF₆, SiCl₄, HBr, NF₃, CF₄, CHF₃, CH₂F₃, F, Cl₂, CCl₄, BCl₃ and SiF₄, among others, and other gases such as O₂, or N₂O.

The angle formed between the anti-wetting coating/liquid interface 230 and the liquid/vapor interface 240 is referred to as a contact angle (also referred to herein as a “wetting angle”).

A drop with a wetting angle of 0 (a=0) is exemplified by spreading of the solution on the surface, as illustrated in row 250. A drop with a wetting angle of less than about 90° (a<90°) is exemplified by good wetting illustrated in row 260. A drop with a wetting angle of about 90° (a=90°) is exemplified by incomplete wetting illustrated in row 270. A drop with a wetting angle of at least about 90° (a>90°) is exemplified by incomplete wetting (leaning towards no wetting) illustrated in row 280. A drop with a wetting angle of at least about 180° (a>180°) is exemplified with no wetting illustrated in row 290.

Anti-wetting coatings discussed herein comprise materials that eliminate or reduce surface adsorption or wetting of corrosive materials. Illustrative corrosive materials that may be repelled from the anti-wetting coating include corrosive amine and silane based precursors, such as SiH₄, chlorosilane, di-chlorosilane, or NH₃ and/or residual gases such as chlorine, sulphur, and H₂S on various articles made from a variety of materials including but not limited to stainless steel, aluminum alloys, ceramic and carbide surfaces (such as SiC).

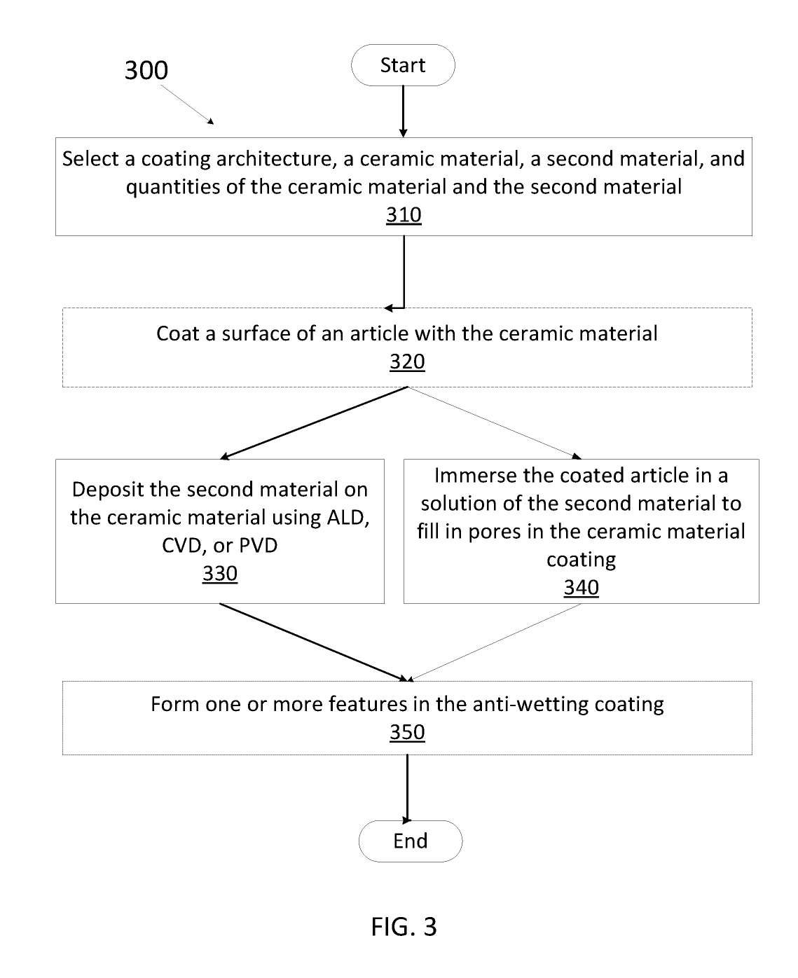

FIG. 3 is a flow chart showing a method 300 for depositing an anti-wetting coating on an article, in accordance with one embodiment. At block 310, the coating architecture, ceramic material, second material, and quantities of the ceramic material and the second material may be selected.

For instance, the coating architecture may be a single layer or a multilayer architecture. A multilayer architecture may comprise two or more layers of ceramic material and the second material. For architecture comprising more than two layers, the ceramic material layer and the second material layer could be deposited in a variety of sequences such as alternating or random sequence. For a single layer, the second material may be utilized to fill in the pores in a porous ceramic material coating.

Suitable ceramic materials may include one or more of yttria (Y₂O₃), silica (SiO₂), alumina (Al₂O₃), erbium oxide (Er₂O₃), gadolinium oxide (Gd₂O₃), zirconia (ZrO₂), boron oxide (B₂O₃), Nd₂O₃, Nb₂O₅, CeO₂, Sm₂O₃, Yb₂O₃, other oxides, Y₃Al₅O₁₂, Y₄Al₂O₉, Er₃Al₅O₁₂, Gd₃Al₅O₁₂, a ceramic compound comprising Y₄Al₂O₉ and a solid-solution of Y₂O₃—ZrO2, and combinations thereof. Suitable materials may also include any of the other ceramic materials that were previously mentioned for use in the ceramic material.

Suitable second materials may be selected from the group consisting of pure amorphous silicon, hydrogenated silicon, silicon hydride, polytetrafluoroethylene (PTFE), prefluoroalkoxy alkanes (PFA), fluorine ethylene propylene (FEP), polyvinylidene fluoride (PVDF), low density polyethylene (PELD), ethylene tetrafluoroethylene (ETFE) and combinations thereof.

If during the selection process, it is determined that a ceramic material will be present in the anti-wetting coating, a ceramic material may be coated on a surface of an article, in accordance with block 320. In one embodiment, the ceramic material may be coated on the surface of the article using atomic layer deposition (ALD). In one embodiment, the ceramic material may be coated on the surface of the article using chemical vapor deposition (CVD). In one embodiment, the ceramic material may be coated on the surface of the article using physical vapor deposition (PVD). In one embodiment, the ceramic material may be coated on the surface of the article using thermal spray. In one embodiment, the ceramic material may be coated on the surface of the article using an immersion method. In one embodiment, the ceramic material may be coated on the surface of the article using e-beam ion assisted deposition (e-beam IAD). In one embodiment, the ceramic coating may be formed on the surface of the article using anodization. For example, anodization may be performed if the article is an aluminum or aluminum alloy article. In other embodiments, the ceramic material may be coated on the surface of the article using other deposition techniques deemed suitable by one of ordinary skill in the art (such as line of sight deposition techniques).

In one embodiment, the second material may be coated on the surface of the article using ALD and/or MLD pursuant to block 330. In one embodiment, the second material may be coated on the surface of the article using CVD pursuant to block 330. In one embodiment, the second material may be coated on the surface of the article using PVD pursuant to block 330.

The method of forming an anti-wetting coating may comprise coating a surface of an article with a ceramic material using a technique selected from the group consisting of ALD, CVD, PVD, thermal spray, and immersion pursuant to block 320. The ceramic coating may form a first layer that may be coated with a second layer of the second material using ALD, CVD, MLD, or PVD pursuant to block 330. Alternatively, for porous ceramic coatings (e.g., ceramic coatings having a porosity of about 1%-50%, about 2%-30%, about 2%-15%, about 2%-10%, or about 2%-5%) the coated article may be immersed in a solution of the second material so that the second material may fill in the pores and/or smooth the roughness of the ceramic material coating, pursuant to block 340.

In some embodiments, a ceramic material may be omitted from the anti-wetting coating and the second material may be deposited directly onto the surface of the article. In such embodiments, the second material may be coated on the surface of the article as the anti-wetting coating. Alternatively, if the article is made of a porous material (e.g., anodized aluminum having a porosity of about 10-15%), the article may be immersed in a solution of the second material allowing the second material to fill in the pores of the porous ceramic material. In an exemplary embodiment, an anodized aluminum article having a porosity of 10-15% may be doped with PTFE. The PTFE may clog the pores in the anodized article. Impregnating the anodized aluminum article with PTFE may increase the operating temperature that may be used with the anodized aluminum article from about 200-300° C. to about 500° C.

In some embodiments, the anti-wetting coating is formed by alternating deposition of a ceramic material by ALD and deposition of a second material by MLD.

Anti-wetting coatings formed by method 300 may have a wetting angle of at least about 90°, at least about 100°, at least about 110°, or at least about 120°. In some embodiments, the anti-wetting coatings may have a wetting angle ranging from about 90° to about 120°.

In some embodiments, the article coated may be a semiconductor process chamber component such as an electrostatic chuck, a lid, a nozzle, a gas distribution plate, a shower head, an electrostatic chuck component, a chamber wall, a liner, a liner kit, a chamber lid, a single ring, a processing kit ring, a gas line, and so on. For articles with high aspect ratios (e.g., aspect ratios of 10:1 to 300:1), ALD may be performed to form the anti-wetting coating. Examples of articles that may have such high aspect ratios (e.g., of a feature's length to width or length to diameter) include gas lines, gas distribution plates and showerheads.

In some embodiments, the method of coating an article with an anti-wetting coating may further comprise forming one or more features in the anti-wetting coating, in accordance with block 350. Forming one or more features may include grinding and/or polishing the anti-wetting coating, drilling holes in the anti-wetting coating, cutting and/or shaping the anti-wetting coating, roughening the anti-wetting coating (e.g., by bead blasting), forming mesas on the anti-wetting coating, and so forth. In one embodiment, the one or more features may comprise at least one of holes, channels, or mesas. Alternatively, features may be formed prior to deposition of the anti-wetting coating in some embodiments.

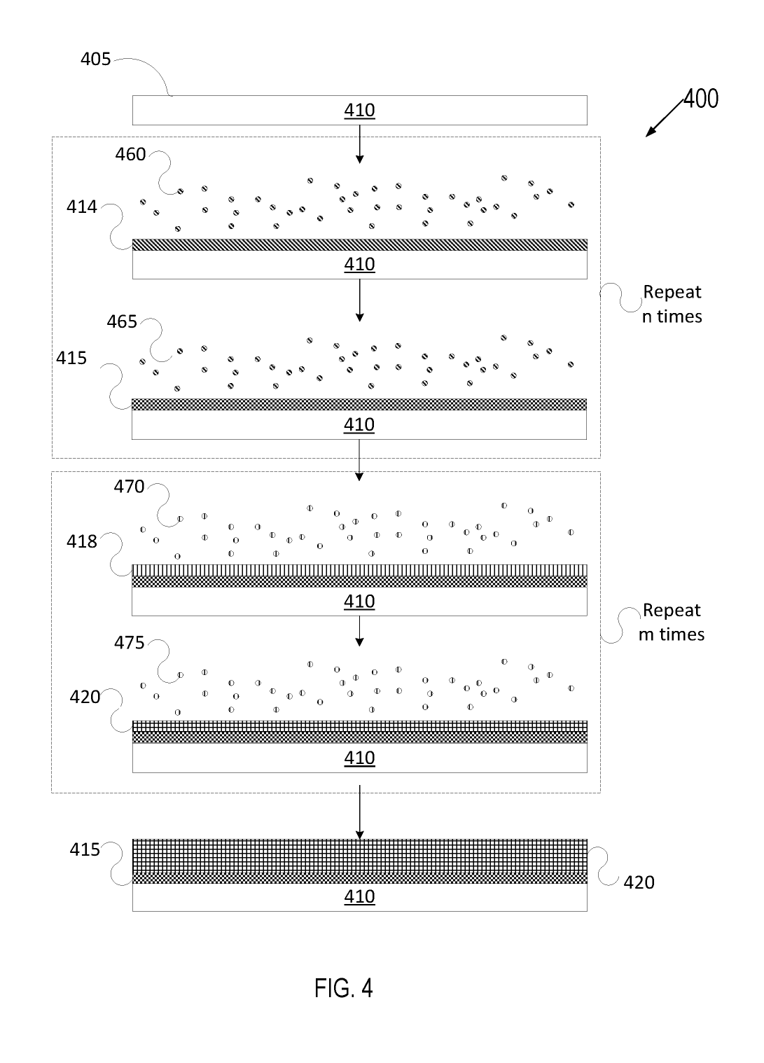

FIG. 4 depicts a deposition process in accordance with a variety of ALD techniques. Various types of ALD processes exist and the specific type may be selected based on several factors such as the surface to be coated, the coating material, chemical interaction between the surface and the coating material, etc. The general principle of an ALD process comprises growing or depositing a thin film layer by repeatedly exposing the surface to be coated to sequential alternating pulses of gaseous chemical precursors that chemically react with the surface one at a time in a self-limiting manner.

FIG. 4 illustrates an article 410 having a surface 405. Each individual chemical reaction between a precursor and the surface is known as a “half-reaction.” During each half reaction, a precursor is pulsed onto the surface for a period of time sufficient to allow the precursor to fully react with the surface. The reaction is self-limiting as the precursor will react with a finite number of available reactive sites on the surface, forming a uniform continuous adsorption layer on the surface. Any sites that have already reacted with a precursor will become unavailable for further reaction with the same precursor unless and/or until the reacted sites are subjected to a treatment that will form new reactive sites on the uniform continuous coating. Exemplary treatments may be plasma treatment, treatment by exposing the uniform continuous adsorption layer to radicals, or introduction of a different precursor able to react with the most recent uniform continuous film layer adsorbed to the surface.

In FIG. 4, article 410 having surface 405 may be introduced to a first precursor 460 for a first duration until a first half reaction of the first precursor 460 with surface 405 partially forms film layer 415 by forming an adsorption layer 414. Subsequently, article 410 may be introduced to a first reactant 465 that reacts with the adsorption layer 414 to fully form the layer 415. The first precursor 460 may be a precursor containing metals for forming a ceramic material, such as a precursor for yttria (Y₂O₃), silica (SiO₂), alumina (Al₂O₃), erbium oxide (Er₂O₃), gadolinium oxide (Gd₂O₃), zirconia (ZrO₂), boron oxide (B₂O₃), Nd₂O₃, Nb₂O₅, CeO₂, Sm₂O₃, Yb₂O₃, other oxides, Y₃Al₅O₁₂, Y₄Al₂O₉, Er₃Al₅O₁₂, Gd₃Al₅O₁₂, or a ceramic compound comprising Y₄Al₂O₉ and a solid-solution of Y₂O₃—ZrO₂, or any of the other aforementioned ceramic materials. The first reactant 465 may be an oxygen reactant if the layer 415 is an oxide or a fluorine reactant if the layer 415 if a fluoride. The article 410 may also be exposed to the first precursor 460 and first reactant 465 up to n number of times to achieve a target thickness for the layer 415. The value of n may be an integer from 1 to 100, for example.

Film layer 415 may be a uniform, continuous and conformal. The film layer 415 may also have a very low porosity of less than 1% in embodiments, less than 0.1% in some embodiments, or approximately 0% in further embodiments.

Subsequently, article 410 having surface 405 and film layer 415 may be introduced to a second precursor 470 that reacts with layer 415 to partially form a second film layer 420 by forming a second adsorption layer 418. The second precursor 470 may be a precursor for the second material, such as a precursor for pure amorphous silicon, hydrogenated silicon, silicon hydride, polytetrafluoroethylene (PTFE), prefluoroalkoxy alkanes (PFA), fluorine ethylene propylene (FEP), polyvinylidene fluoride (PVDF), low density polyethylene (PELD), ethylene tetrafluoroethylene (ETFE) and combinations thereof. Exemplary precursors for the second material may include, but not be limited to, silanes, metal acetylacetonates, beta-diketonates or alkoxides, alkoxysilanols precursors suspended in alcohol, water etc.

Subsequently, article 410 may be introduced to another reactant 475 that reacts with adsorption layer 418 leading to a second half reaction to fully form the layer 420. The article 410 may alternately be exposed to the second precursor 470 and second reactant 475 up to m number of times to achieve a target thickness for the layer 420. m may be an integer from 1 to 100, for example. Layer 420 may be an anti-wetting top capping layer which may, in some embodiments, act as a sacrificial layer. Oxygen may be a non-limiting exemplary reactant.

The second film layer 420 may be uniform, continuous and conformal. The second film layer 420 may also have a very low porosity of less than 1% in some embodiments, less than 0.1% in some embodiments, or approximately 0% in further embodiments.

In a similar manner, article 410 may continue to be introduced sequentially to the same or to other precursors and reactants until a final anti-wetting coating according to an embodiment is formed.

The surface reactions (e.g., half-reactions) described above, such as the reaction between the article's surface and the precursor(s) or the reaction between the precursor(s) and the reactant(s), are done sequentially. Prior to introduction of a new precursor(s) and/or a new reactant(s), the chamber in which the ALD process takes place may be purged with an inert carrier gas (such as nitrogen or air) to remove any unreacted precursors and/or reactants and/or surface-precursor reaction byproducts.

ALD processes may be conducted at various temperatures. The optimal temperature range for a particular ALD process is referred to as the “ALD temperature window.” Temperatures below the ALD temperature window may result in poor growth rates and non-ALD type deposition. Temperatures above the ALD temperature window may result in thermal decomposition of the article or rapid desorption of the precursor. The ALD temperature window may range from about 100° C. to about 400° C. In some embodiments, the ALD temperature window is between about 150° C. to about 350° C.

The ALD process allows for conformal film layers having uniform film thickness on articles and surfaces having complex geometric shapes, complex surface features, holes with large aspect ratios, and three-dimensional structures. Sufficient exposure time of the precursors to the surface enables the precursors to disperse and fully react with the surface in its entirety, including all of its three-dimensional complex features. The exposure time utilized to obtain conformal ALD in high aspect ratio structures is proportionate to the square of the aspect ratio and can be predicted using modeling techniques. The ALD technique may produce relatively thin (i.e., 1 μm or less) coatings that are porosity free (i.e. pin-hole free), which may prevent, reduce, or eliminate crack formation during deposition. The term “porosity-free” as used herein means absence of any pores, pin-holes, voids, or cracks along the whole depth of the coating as measured by transmission electron microscopy (TEM).

ALD techniques described herein may be utilized for coating an article with anti-wetting coatings contemplated herein. Additionally, ALD chambers where substrates are coated using the ALD techniques could benefit from having chamber components coated with anti-wetting coatings described herein. Without such anti-wetting coatings, chemicals like amines and silanes used in ALD chambers and processes tend to remain in the ALD chambers and create parasitic chemical vapor deposition which hinders pure ALD coating on substrates. By utilizing chamber components with anti-wetting coating, corrosive chemicals get fully purged enabling a pure ALD process on the substrate.

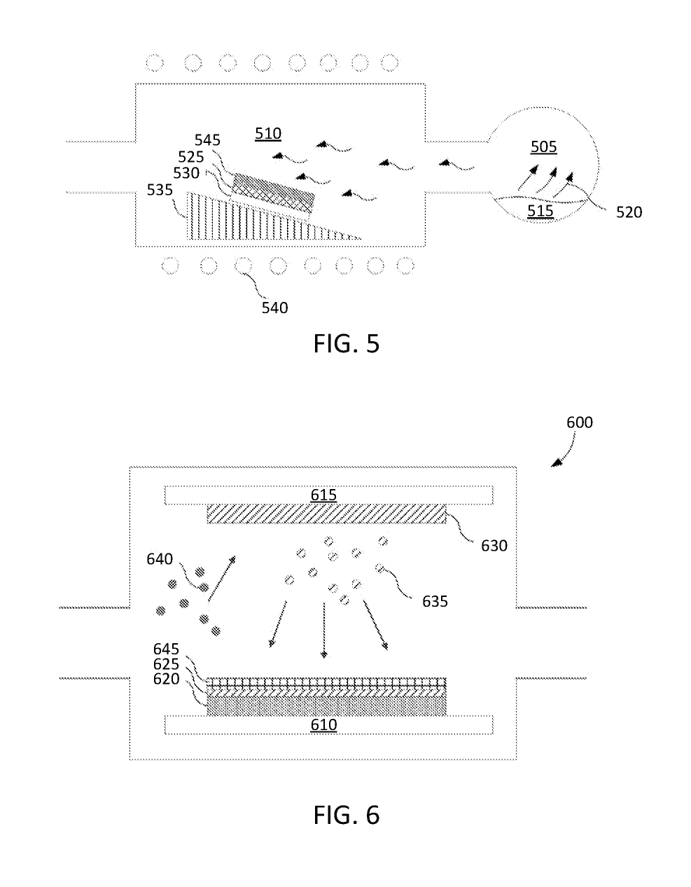

In some embodiments, the anti-wetting coating may be deposited on a surface of an article via CVD. An exemplary CVD system is illustrated in FIG. 5. The system comprises a chemical vapor precursor supply system 505 and a CVD reactor 510. The role of the vapor precursor supply system 505 is to generate vapor precursors 520 from a starting material 515, which could be in a solid, liquid, or gas form. The vapors may subsequently be transported into CVD reactor 510 and get deposited as an anti-wetting coat 525 and/or 545 on the surface of article 530, in accordance with an embodiment, which may be positioned on article holder 535.

CVD reactor 510 heats article 530 to a deposition temperature using heater 540. In some embodiments, the heater may heat the CVD reactor's wall (also known as “hot-wall reactor”) and the reactor's wall may transfer heat to the article. In other embodiments, the article alone may be heated while maintaining the CVD reactor's wall cold (also known as “cold-wall reactor”). It is to be understood that the CVD system configuration should not be construed as limiting. A variety of equipment could be utilized for a CVD system and the equipment is chosen to obtain optimum processing conditions that may give a coating with uniform thickness, surface morphology, structure, and composition.

The various CVD techniques include the following phases: (1) generate active gaseous reactant species (also known as “precursors”) from the starting material; (2) transport the precursors into the reaction chamber (also referred to as “reactor”); (3) absorb the precursors onto the heated article; (4) participate in a chemical reaction between the precursor and the article at the gas-solid interface to form a deposit and a gaseous by-product; and (5) remove the gaseous by-product and unreacted gaseous precursors from the reaction chamber.

Suitable CVD precursors may be stable at room temperature, may have low vaporization temperature, can generate vapor that is stable at low temperature, have suitable deposition rate (low deposition rate for thin film coatings and high deposition rate for thick film coatings), relatively low toxicity, be cost effective, and relatively pure. For some CVD reactions, such as thermal decomposition reaction (also known as “pyrolysis”) or a disproportionation reaction, a chemical precursor alone may suffice to complete the deposition. For other CVD reactions, other agents (listed in Table 1 below) in addition to a chemical precursor may be utilized to complete the deposition.

TABLE 2
Chemical Precursors and Additional Agents
Utilized in Various CVD Reactions

| CVD reaction | Chemical Precursor | Additional Agents |
|---|---|---|
| Thermal Decomposition | Halides | N/A |
| (Pyrolysis) | Hydrides | |
| | Metal carbonyl | |
| | Metalorganic | |
| Reduction | Halides | Reducing agent |
| Oxidation | Halides | Oxidizing agent |
| | Hydrides | |
| | Metalorganic | |
| Hydrolysis | Halides | Hydrolyzing agent |
| Nitridation | Halides | Nitriding agent |
| | Hydrides | |
| | Halohydrides | |
| Disproportionation | Halides | N/A |

CVD has many advantages including its capability to deposit highly dense and pure coatings and its ability to produce uniform films with good reproducibility and adhesion at reasonably high deposition rates. Layers deposited using CVD in embodiments may have a porosity of below 1%, and a porosity of below 0.1% (e.g., around 0%). Therefore, it can be used to uniformly coat complex shaped components and deposit conformal films with good conformal coverage (e.g., with substantially uniform thickness).

The CVD reactor 510 may be used to form an anti-wetting coating that is resistant to adsorption of corrosive chemicals in embodiments. Anti-wetting coating 525 and 545 may comprise an optional ceramic material and/or may comprise a second material selected from the group consisting of pure amorphous silicon, hydrogenated silicon, silicon hydride, PTFE, PFA, FEP, PVDF, PELD, ETFE, and combinations thereof. The optional ceramic material may comprise yttria (Y₂O₃), silica (SiO₂), alumina (Al₂O₃), erbium oxide (Er₂O₃), gadolinium oxide (Gd₂O₃), zirconia (ZrO₂), boron oxide (B₂O₃), Nd₂O₃, Nb₂O₅, CeO₂, Sm₂O₃, Yb₂O₃, other oxides, Y₃Al₅O₁₂, Y₄Al₂O₉, Er₃Al₅O₁₂, Gd₃Al₅O₁₂, a ceramic compound comprising Y₄Al₂O₉ and a solid-solution of Y₂O₃—ZrO2, or any of the other oxides and/or fluorides described above for use as the ceramic material.

The anti-wetting coating may comprise a bilayer or a multilayer architecture, various layers may have similar or different thicknesses, and the layers may independently be crystalline or amorphous. In some embodiments, the protective coat may be subject to post coating heat treatment. In some embodiments, the protective coat may be subject to post coating processing to form one or more features therein.

In some embodiments, the anti-wetting coating may be deposited on a surface of an article via a PVD technique. PVD processes may be used to deposit thin films with thicknesses ranging from a few nanometers to several micrometers. The various PVD processes share three fundamental features in common: (1) evaporating the material from a solid source with the assistance of high temperature or gaseous plasma; (2) transporting the vaporized material in vacuum to the article's surface; and (3) condensing the vaporized material onto the article to generate a thin film layer. An illustrative PVD reactor is depicted in FIG. 6 and discussed in more detail below.

FIG. 6 depicts a deposition mechanism applicable to a variety of PVD techniques and reactors. PVD reactor chamber 600 may comprise a plate 610 adjacent to the article 620 and a plate 615 adjacent to the target 630. Air may be removed from reactor chamber 600, creating a vacuum. Then argon gas or another inert gas may be introduced into the reactor chamber, voltage may be applied to the plates, and a plasma comprising electrons and positive argon ions 640 may be generated. Positive argon ions 640 may be attracted to negative plate 615 where they may hit target 630 and release atoms 635 from the target. Released atoms 635 may get transported and deposited as anti-wetting coat 625 and/or 645 onto article 620, in accordance with an embodiment.

The PVD reactor chamber 600 may be used to form an anti-wetting coating in embodiments. Anti-wetting coating 625 and 645 may comprise any of the aforementioned ceramic materials and/or second materials.

The anti-wetting coat may comprise a bilayer or a multilayer architecture, various layers may have similar or different thicknesses, and the layers may independently be crystalline or amorphous. In some embodiments, the protective coat may be subject to post coating heat treatment. In some embodiments, the anti-wetting coat may be subject to post coating processing to form one or more features therein.

In some embodiments, the anti-wetting coating may be deposited on a surface of an article via a MLD technique and/or a combination of ALD and MLD. Like ALD deposition of conformal thin inorganic films, the MLD technique for depositing organic layers can be used to make three dimensional (3D) conformal high quality thin film coatings with growth and composition control on the molecular scale. MLD may be performed to produce polyamide, polyimide, polyimide-amide, polyurea, polyurethane, polythiurea, polyester and/or polyimine thin films. For example, polyamides are polymers in which the precursors employed are combined with each other via amide bond formation, whereas polyureas contain a urea linkage. Polyimide-amides polymers contain both an imide and an amide group. Any of the above referenced materials may be deposited by MLD to form an anti-wetting coating. For example, a polymer that provides a highest contact angle for anti-stick properties on films may be selected, and then deposited onto an article using MLD.

In some embodiments, an anti-wetting coating may be deposited by a combination of ALD and MLD. Using the two techniques, ALD and MLD, new & complex types of inorganic-organic hybrid coatings can be synthesized. In one embodiment, deposition of an anti-wetting coating may include performing multiple ALD/MLD cycles. An ALD/MLD cycle may include the following four steps:

1) A first (inorganic) precursor is pulsed to the reactor and it reacts with a surface species. The inorganic precursor may be any of the aforementioned inorganic precursors, such as rare earth precursors;
2) Excess precursor and possible byproducts are removed from the reactor, either by purging with inert gas such as nitrogen or argon, or by evacuation;
3) A second (organic) precursor is pulsed to the reactor, and it reacts with the surface species; and
4) Excess precursor/possible byproducts are removed from the reactor.
The ALD/MLD cycle may form a monolayer of a hybrid inorganic-organic material. To deposit thicker films this basic ALD/MLD cycle is repeated as many times as needed to reach a targeted film thickness.

For pure organic MLD films r is typically lower than 0.5, where r=growth per cycle (GPC)/ML, where the monolayer (ML) is the ideal length of the M−R monomer. Values of r may vary with different precursor combinations. For hybrid inorganic-organic thin films formed by the ALD/MLD process, there may be a larger variation in r values depending on the organic precursor employed.

The thin films formed by MLD or ALD/MLD can be grown at temperatures in the temperature range of 85-175° C. The GPC value for the thin film may vary from 0.4 to 4.5 Å per cycle, decreasing with increasing deposition temperature. Thickness from 10 nm to 100's of nm can be deposited using the MLD process or the ALD/MLD process. Accordingly, the MLD and ALD/MLD processes may be used to control thickness & conformal growth of thin films. Such thin films may be pinhole free, dense (e.g., with 0% or approximately 0% porosity, such as less than 0.1% porosity) and uniform coatings.

Characterization techniques used to check MLD deposited coatings are similar to inorganic thin films grown by ALD. An in situ quartz crystal microbalance (QCM) may be used to give some insight on the growth dynamics of the deposition. Besides thickness measurements, X-ray reflectivity (XRR) can be used for evaluating densities and roughness of the thin films. The crystallinity of the films may be examined by X-ray diffraction (XRD). The topography of the films can be investigated by using atomic force microscopy (AFM). Fourier transform infrared (FTIR) spectroscopy is useful for analyzing the chemical state of the films. X-ray photoelectron spectroscopy (XPS) gives the composition of films, whereas the presence of a metal can be verified by X-ray fluorescence (XRF) measurements. Nano-indentation gives insight on the mechanical properties of the films.

FIGS. 4, 5, 6 and the above description about the ALD, CVD, MLD, ALD/MLD and PVD processes illustrate a multi-layered architecture comprising a layer of a ceramic material deposited by ALD, CVD, MLD, ALD/MLD or PVD and a layer of the second material deposited by ALD, CVD, MLD, ALD/MLD or PVD. However, this description should not be construed in a limiting manner. It should be understood that in some embodiments, the second material may be deposited directly onto an article without any ceramic material. In some embodiments, it may be beneficial to include both the ceramic and the second material in the anti-wetting coating. When beneficial to have both the ceramic and second material in the anti-wetting coating, the ceramic material and the second material may be deposited by the same or by different techniques independently selected from ALD, CVD, PVD, e-beam IAD, MLD, ALD/MLD, immersion and so on.

In an exemplary embodiment, an anti-wetting coating comprising a combination of PTFE and yttria may be erosion resistant, have an unchanged or improved breakdown voltage, and have an increased dielectric strength, hardness and flexural strength which would protect the coated article from high plasma environments and minimize cracks in the article coating. The values for physical and chemical properties of the anti-wetting coating (e.g., erosion resistance, breakdown voltage, dielectric strength, hardness, and flexural strength) may be between the same property's value for pure plastics and pure ceramics.

Article 410 in FIG. 4, article 530 in FIG. 5, article 620 in FIG. 6, and all other articles discussed herein may represent various semiconductor process chamber components or other chamber components including but not limited to substrate support assembly, an electrostatic chuck (ESC), an electrostatic chuck component, a ring (e.g., a process kit ring or single ring), a chamber wall, a base, a gas distribution plate, gas lines, a showerhead, a nozzle, a lid, a chamber lid, a liner, a liner kit, a shield, a plasma screen, a flow equalizer, a cooling base, a chamber viewport, a chamber lid, bellows, and so on.

The articles and their surfaces may be made from a metal (such as aluminum, stainless steel), a ceramic, a metal-ceramic composite, a polymer, a polymer ceramic composite, or other suitable materials, and may further comprise materials such as AN, Si, SiC, Al₂O₃, SiO₂, anodized aluminum, aluminum, aluminum alloy (e.g., Al 6061), anodized aluminum alloy, and so on.

With the deposition techniques described herein and other deposition techniques understood by one of ordinary skill in the art as equivalent and/or suitable, anti-wetting coatings can be formed. The anti-wetting coatings disclosed herein provide good erosion and/or corrosion resistance to the coated article. Additionally, there is a reduced likelihood of parasitic CVD on substrates that may get processed in chambers comprising chamber components coated with the anti-wetting coatings disclosed herein. The beneficial properties of the anti-wetting coatings disclosed herein may be independent from the deposition techniques in certain embodiments.

Exemplary yttrium-containing precursors that may be utilized with the CVD and ALD coating deposition techniques include, but are not limited to, tris(N,N-bis(trimethylsilyl)amide)yttrium (III), yttrium (III)butoxide, tris(cyclopentadienyl)yttrium(III), and Y(thd)3 (thd=2,2,6,6-tetramethyl-3,5-heptanedionato).

Exemplary silicon-containing precursors that may be utilized with the ALD and CVD coating deposition techniques include, but are not limited to, 2, 4, 6, 8-tetramethylcyclotetrasiloxane, dimethoxydimethylsilane, disilane, methylsilane, octamethylcyclotetrasiloxane, silane, tris(isopropoxy)silanol, tris(tert-butoxy)silanol, and tris(tert-pentoxy) silanol.

Exemplary aluminum-containing precursors that may be utilized with the ALD and CVD coating deposition technique include, but are not limited to, diethylaluminum ethoxide, tris(ethylmethylamido)aluminum, aluminum sec-butoxide, aluminum tribromide, aluminum trichloride, triethylaluminum, triisobutylaluminum, trimethylaluminum, or tris(diethylamido)aluminum.

Exemplary erbium-containing precursors that may be utilized with the ALD and CVD coating deposition technique include, but are not limited to, tris-methylcyclopentadienyl erbium (III) (Er(MeCp)₃), erbium boranamide (Er(BA)₃), Er(TMHD)₃, erbium(III) tris(2,2,6,6-tetramethyl-3,5-heptanedionate), and tris(butylcyclopentadienyl)erbium(III).

Exemplary zirconium-containing precursors that may be utilized with the ALD and CVD coating deposition technique include, but are not limited to, zirconium (IV) bromide, zirconium (IV) chloride, zirconium (IV) tert-butoxide, tetrakis(diethylamido)zirconium (IV), tetrakis(dimethylamido)zirconium (IV), or tetrakis(ethylmethylamido)zirconium (IV).

Other exemplary precursors for the second material that may be utilized with the ALD and CVD coating deposition technique, include, but are not limited to, silanes, metal acetylacetonates or beta-diketonates or alkoxides, alkoxysilanols precursors suspended in alcohol, water etc.

Exemplary oxygen-containing reactants that may be utilized with the various coating deposition techniques identified herein and their equivalent include, but are not limited to, ozone, water vapor, and oxygen radicals.

The preceding description sets forth numerous specific details such as examples of specific systems, components, methods, and so forth, in order to provide a good understanding of several embodiments of the present disclosure. It will be apparent to one skilled in the art, however, that at least some embodiments of the present disclosure may be practiced without these specific details. In other instances, well-known components or methods are not described in detail or are presented in simple block diagram format in order to avoid unnecessarily obscuring the present disclosure. Thus, the specific details set forth are merely exemplary. Particular embodiments may vary from these exemplary details and still be contemplated to be within the scope of the present disclosure.

Reference throughout this specification to “one embodiment” or “an embodiment” means that a particular feature, structure, or characteristic described in connection with the embodiment is included in at least one embodiment. Thus, the appearances of the phrase “in one embodiment” or “in an embodiment” in various places throughout this specification are not necessarily all referring to the same embodiment. In addition, the term “or” is intended to mean an inclusive “or” rather than an exclusive “or.”

Reference throughout this specification to numerical ranges should not be construed as limiting and should be understood as encompassing the outer limits of the range as well as each number and/or narrower range within the enumerated numerical range.

Although the operations of the methods herein are shown and described in a particular order, the order of the operations of each method may be altered so that certain operations may be performed in an inverse order or so that certain operation may be performed, at least in part, concurrently with other operations. In another embodiment, instructions or sub-operations of distinct operations may be in an intermittent and/or alternating manner.

It is to be understood that the above description is intended to be illustrative, and not restrictive. Many other embodiments will be apparent to those of skill in the art upon reading and understanding the above description. The scope of the disclosure should, therefore, be determined with reference to the appended claims, along with the full scope of equivalents to which such claims are entitled.

What is claimed is:

1. A component comprising:
an article; and
an anti-wetting coating comprising a ceramic material and a second material, wherein the second material is selected from the group consisting of pure amorphous silicon, hydrogenated silicon, silicon hydride, polytetrafluoroethylene (PTFE), perfluoroalkoxy alkanes (PFA), fluorinated ethylene propylene (FEP), polyvinylidene fluoride (PVDF), low density polyethylene (PELD), polyamide, polyimide, polyimide-amide, polyurea, polyurethane, polythiurea, polyester, polyimine, and combinations thereof, and
wherein the component has a wetting angle of at least about 90°.

2. The component of claim 1, wherein the component has a wetting angle of at least about 120°.

3. The component of claim 1, wherein the article is selected from a group consisting of an electrostatic chuck, a lid, a nozzle, a gas distribution plate, a shower head, an electrostatic chuck component, a chamber wall, a liner, a liner kit, a chamber lid, a nozzle, a single ring, a processing kit ring, and a gas line.

4. The component of claim 1, wherein the anti-wetting coating is conformal.

5. The component of claim 1, wherein the anti-wetting coating comprises a multilayer architecture, wherein the multilayer architecture comprises a first layer comprising the ceramic material and a second layer comprising the second material.

6. The component of claim 5, wherein the first layer and the second layer, independently, have a thickness ranging from about 10 nm to about 490 nm.

7. The component of claim 1, wherein the anti-wetting coating has a thickness of about 100 nm to about 500 nm.

8. The component of claim 1, wherein the ceramic material defines pores and has a porosity ranging from about 1% to about 50%, and wherein the second material fills in the pores in the ceramic material.

9. The component of claim 1, wherein the anti-wetting coating comprises the second material at a concentration ranging from about 1 wt % to about 50 wt % based on total weight of the anti-wetting coating.

10. The component of claim 1, wherein the ceramic material has a surface roughness ranging from about 125 μ-in to about 300 μ-in, and wherein the anti-wetting coating has a surface roughness of about 10 μ-in to about 80 μ-in.

11. A method for forming an anti-wetting coating on an article, the method comprising:
coating a surface of an article with a ceramic material; and
coating the ceramic material with a second material selected from the group consisting of pure amorphous silicon, hydrogenated silicon, silicon hydride, polytetrafluoroethylene (PTFE), perfluoroalkoxy alkanes (PFA), fluorinated ethylene propylene (FEP), polyvinylidene fluoride (PVDF), low density polyethylene (PELD), polyamide, polyimide, polyimide-amide, polyurea, polyurethane, polythiurea, polyester, polyimine, and combinations thereof, to form the anti-wetting coating,
wherein the anti-wetting coating has a wetting angle of at least about 90°.

12. The method of claim 11, wherein the anti-wetting coating has a wetting angle of at least 120°.

13. The method of claim 11, wherein coating the ceramic material with a second material comprises depositing the second material by atomic layer deposition (ALD), molecular layer deposition (MLD), chemical vapor deposition (CVD), or physical vapor deposition (PVD).

14. The method of claim 11, wherein the anti-wetting coating comprises the second material at a concentration ranging from about 1 wt % to about 50 wt % based on total weight of the anti-wetting coating.

15. The method of claim 11, wherein the ceramic material defines pores and has a porosity ranging from about 1% to about 50%, and wherein the second material fills in the pores in the ceramic material.

16. The method of claim 15, wherein coating the ceramic material with the second material comprises immersing the article coated with the ceramic material in a solution comprising the second material.

17. The method of claim 11, wherein the anti-wetting coating comprises a multilayer architecture, wherein the multilayer architecture comprises a first layer comprising the ceramic material and a second layer comprising the second material, and wherein the first layer and the second layer, independently, have a thickness ranging from about 10 nm to about 490 nm.

18. The method of claim 11, wherein the anti-wetting coating has a thickness of about 100 nm to about 500 nm.

19. An anti-wetting coating comprising:
a ceramic material; and
a second material selected from the group consisting of pure amorphous silicon, hydrogenated silicon, silicon hydride, polytetrafluoroethylene (PTFE), perfluoroalkoxy alkanes (PFA), fluorinated ethylene propylene (FEP), polyvinylidene fluoride (PVDF), low density polyethylene (PELD), and combinations thereof,
wherein the anti-wetting coating has a wetting angle of at least about 90°.

20. The anti-wetting coating of claim 19, wherein the anti-wetting coating has a wetting angle of at least about 120°.
